(19) United States
(12) Patent Application Publication
(10) Pub. No.: US 2012/0147551 A1
(43) Pub. Date: Jun. 14, 2012

(54) SERVER CABINET

(75) Inventor: ZEU-CHIA TAN, Tu-Cheng (TW)

(73) Assignee: HON HAI PRECISION INDUSTRY CO., LTD., Tu-Cheng (TW)

(21) Appl. No.: 13/070,528

(22) Filed: Mar. 24, 2011

(30) Foreign Application Priority Data
Dec. 8, 2010 (TW) 99142792

(51) Int. Cl. G06F 1/20; H05K 5/02

(52) U.S. Cl. 361/679.48; 361/679.46; 312/236

(57) ABSTRACT

A server cabinet for receiving a number of servers includes a top plate, a bottom plate, a left side plate, a right side plate, a front side plate, and a rear side plate cooperatively defining a receiving space for receiving the servers. The server cabinet defines a first channel and a second channel in the receiving space. The top plate defines an inlet port communicating with the first channel, and an outlet port communicating with the second channel. Cold air blows from the inlet port into the first channel of the server cabinet, flows through the servers and to the second channel, and flows out from the outlet port for dissipating heat generated by the servers.

### BACKGROUND

1. Technical Field

The disclosure relates to server cabinets and more particularly to a server cabinet facilitating heat dissipation.

2. Description of Related Art

Nowadays, many server systems are used for data storage and data operation. A server system generally includes a server cabinet, and a number of standard servers stacked in the server cabinet, one on top of the other, from the bottom to the top of the server cabinet. The servers generate considerable heat during operation, and may if the heat is not efficiently removed the servers may malfunction or even become damaged.

What is needed, therefore, is a server cabinet for use in a server system which can overcome the limitations described.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, like reference numerals designate corresponding parts throughout the several views.

FIG. 1 is an isometric, assembled view of a server cabinet of a server system in accordance with an embodiment of the disclosure.

FIG. 2 is an assembled view of the server cabinet of FIG. 1 with a front side plate and a rear side plate opened.

FIG. 3 is a cross sectional view of the server cabinet of FIG. 1, and shows an airflow generating device of the server system installed at a top of the server cabinet.

### DETAILED DESCRIPTION

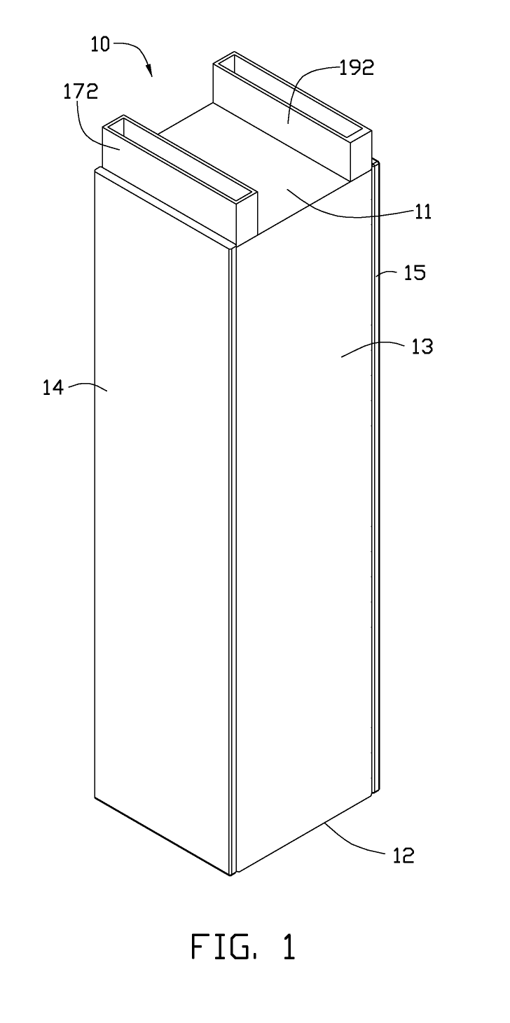

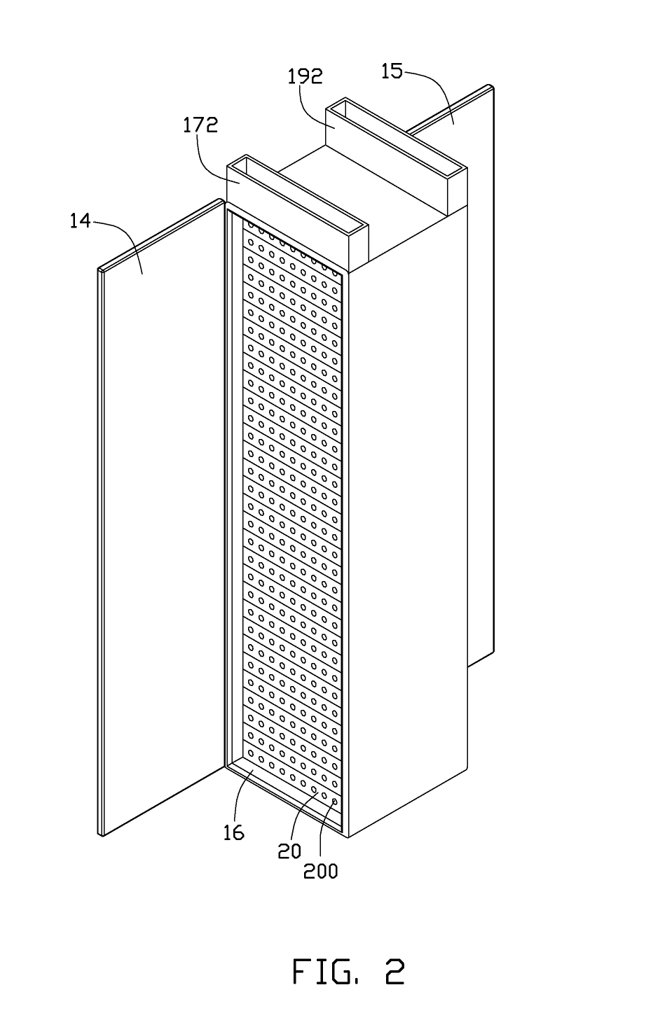

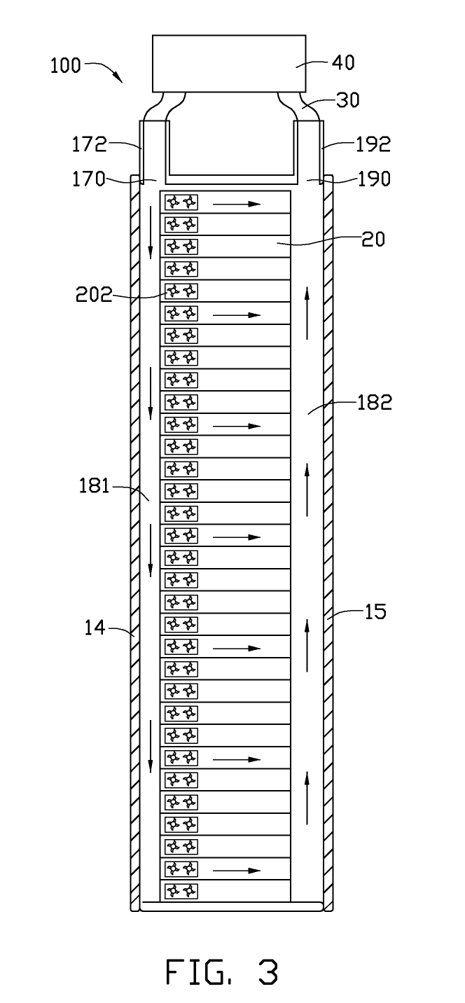

Referring to FIGS. 1-3, a server system 100 in accordance with an embodiment of the disclosure is shown. The server system 100 includes a server cabinet 10, a plurality of standard servers 20 stacked in the server cabinet 10, and an airflow generating device 40 installed above the top of the server cabinet 10. In this embodiment, the airflow generating device 40 is an air conditioner. The server system 100 can be used in, for example, a Container Data Center. The Container Data Center is a data center which is formed by mounting a plurality of server systems in a standard container.

The server cabinet 10 is a rectangular cuboid, and includes a top plate 11, a bottom plate 12 opposite to and parallel to the top plate 11. As well as the left and right side plates 13 respectively connecting the left and right edges of the top and bottom plates 11, 12, a front side plate 14 is installed at the front sides of the top and bottom plates 11, 12. A rear side plate 15 is installed at the rear sides of the top and bottom plates 11, 12. The top and bottom plates 11, 12, the left and right side plates 13, and the front and rear plates 14, 15 cooperatively define a receiving space 16. In this embodiment, the front side plate 14 and the rear side plate 15 pivotably connect front and rear edges of the left side plate 13, respectively. The front side plate 14 and the rear side plate 15 can rotate relative to the left side plate 14 to open or close the receiving space 16. Alternatively, the front side plate 14 and the rear side plate 15 can both be pivotably connected to the right side 13 or be pivotably connected to the left and right side plates 13, respectively. The top side plate 11 defines an inlet port 170 and an outlet port 190 thereon. The inlet port 170 and the outlet port 190 both communicate with the receiving space 16.

The servers 20 are received in the receiving space 16 of the server cabinet 10 and stacked one on top of the other. Each of the servers 20 has left and right sides respectively engaging with the left and right side plates 13 of the server cabinet 10, a front side spaced from the front side plate 14, and a rear side spaced from the rear side plate 15. Therefore, the servers 20 divide the receiving space 16 into a vertical first channel 181 and a vertical second channel 182. The first channel 181 is defined between the front sides of the servers 20 and the front side plate 14 and is aligned with the inlet port 170, and the second channel 182 is defined between the rear sides of the servers 20 and the rear side plate 15 and aligned with the outlet port 190. Each server 20 defines a plurality of through holes 200 respectively in the front and rear sides thereof. A plurality of fans 202 for generating air flow is installed in each server 20. The through holes 200 of each server 20 horizontally communicate with the first channel 181 and the second channel 182.

The server cabinet 10 includes an inlet connector 172 at a front side of the top plate 11 and an outer connector 192 at a rear side of the top plate 11. In this embodiment, the inlet connector 172 extends up from the top plate 11 at a periphery of the inlet port 170, and communicates with the first channel 181 of the server cabinet 10 via the inlet port 170. The outlet connector 192 extends up from the top plate 11 at a periphery of the outlet port 190, and communicates with the second channel 182 of the server cabinet 10 via the outlet port 190. The inlet connector 172 is adapted for guiding air of the airflow generating device 40 into the server cabinet 10 to exchange heat with the servers 20, and the outlet connector 192 is adapted for guiding the heated air out of the server cabinet. Two ducts 30 can be provided to connect the inlet connector 172 and the outlet connector 192 of the server cabinet 10 to the airflow generating device 40 when the airflow generating device 40 is remotely located.

In use, cold (or cooler) air generated by the airflow generating device 40 blows downwards from the inlet port 170 into the first channel 181 of the server cabinet 10. The fans 202 of each server 20 draw the cold air through the through holes 200 in the front sides of the servers 20 and expel hot air to the second channel 182 of the servers 20 via the through holes 200 in the rear sides of the servers 20, to dissipate heat from the servers 20. The hot air in the second channel 182 then flows upward and out from the outlet port 190 and is drawn by the airflow generating device 40 via the outlet connector 192 and the duct 30. The airflow generating device 40 draws the hot air and generates cold air and allows the cold air to circulate in the server cabinet.

Since air flows in the airflow generating device 40, the server cabinet 10 and the servers 20 flows in a substantially hermetic system, much more air can directly flow through to the servers 20 and dissipate more heat generated by the servers 20 from the server cabinet 10. This improves a heat dissipation efficiency of the server system 100.

It is believed that the disclosure and its advantages will be understood from the foregoing description, and it will be apparent that various changes may be made thereto without departing from the spirit and scope of the invention or sacrificing all of its material advantages, the examples hereinbefore described merely being preferred or exemplary embodiments of the invention.

What is claimed is:

1. A server cabinet adapted for receiving a number of servers, the server cabinet comprising:
a top plate and a bottom plate opposite to the top plate; and
a left side plate, a right side plate, a front side plate, and a rear side plate installed between the top and bottom plates, the top plate, the bottom plate, the left side plate, the right side plate, the front side plate, and the rear side plate cooperatively defining a receiving space for receiving the servers, a first channel and a second channel being defined in the receiving space for communicating with the servers, the top plate defining an inlet port communicating with the first channel, and an outlet port communicating with the second channel;
wherein cold air blows from the inlet port into the first channel of the server cabinet, flows through the servers and to the second channel, and flows out from the outlet port for dissipating heat generated by the servers.

2. The server cabinet of claim 1, further comprising an inlet connector extending up from the top plate at a periphery of the inlet port to communicate with the inlet port.

3. The server cabinet of claim 1, further comprising an outlet connector extending up from the top plate at a periphery of the inlet port to communicate with the outlet port of the top plate.

4. The server cabinet of claim 1, wherein the rear side plate pivotably connects one of the left and right side plates.

5. The server cabinet of claim 1, wherein the front side plate pivotably connects one of the left and right side plates.

6. A server system comprising:
a plurality of servers stacked one on another;
a server cabinet receiving the servers, the server cabinet comprising a top plate and a bottom plate opposite to the top plate, a left side plate, a right side plate, a front side plate, and a rear side plate installed between the top and bottom plates, the top plate, the bottom plate, the left side plate, the right side plate, the front side plate, and the rear side plate cooperatively defining a receiving space to receive the servers, the server cabinet defining a first channel with an inlet port and a second channel with an outlet port, the servers communicating with the first channel and the second channel; and
an airflow generating device generating air, the air blowing from the inlet port into the first channel of the server cabinet, flowing through the servers and to the second channel, and flowing out from the outlet port to the airflow generating device to dissipate heat generated by the servers.

7. The server system of claim 6, wherein the inlet port and the outlet port are defined at the top plate.

8. The server system of claim 6, wherein each of the servers has left and right sides engaging with the left and right side plates of the server cabinet, a front side spaced to the front side plate, and a rear side spaced to the rear side plate.

9. The server system of claim 8, wherein the first channel is defined between the front sides of the servers and the front side plate, and the second channel is defined between the rear sides of the servers and the rear side plate.

10. The server system of claim 6, wherein at least one fan is installed in each of the servers.

11. The server system of claim 6, wherein the airflow generating device is an air conditioner.

12. The server system of claim 6, wherein the server cabinet comprises an inlet connector extending up from the top plate at a periphery of the inlet port to communicate with the inlet port of the top plate.

13. The server system of claim 6, wherein the server cabinet comprises an outlet connector extending up from the top plate at a periphery of the inlet port to communicate with the outlet port of the top plate.

14. The server system of claim 6, wherein the front side plate pivotably connects one of the left and right side plates.

15. The server system of claim 6, wherein the rear side plate pivotably connects one of the left and right side plates.
